(19) United States
(12) Patent Application Publication
(10) Pub. No.: US 2016/0223802 A1
(43) Pub. Date: Aug. 4, 2016

(54) SUNLIGHT MANIPULATING DEVICE

(71) Applicant: NATIONAL CHIAO TUNG UNIVERSITY, HSINCHU CITY (TW)

(72) Inventor: CHENG-HUAN CHEN, HSINCHU (TW)

(21) Appl. No.: 15/010,526

(22) Filed: Jan. 29, 2016

(30) Foreign Application Priority Data
Jan. 29, 2015 (TW) 104103089

(51) Int. Cl. G02B 19/00; G02B 3/08; F24J 2/10; G02B 5/26; H01L 31/0232; F24J 2/08; G02B 6/32; G02B 26/08

(52) U.S. Cl. CPC G02B 19/0042; G02B 6/32; G02B 19/0028; G02B 3/08; G02B 26/0816; G02B 5/26; H01L 31/02325; F24J 2/08; F24J 2/10

(57) ABSTRACT

A sunlight manipulating device includes a light focusing module and a light deflection module. The light focusing module is configured for converging incident sunlight on a focal region. The light deflection module is arranged on the focal region or adjacent to the focal region and configured for deflecting the converged sunlight to a target area, wherein the target area is diverged from an optical axis of the light focusing module. The above-mentioned sunlight manipulating device allows more diverse configurations for solar cells, heating devices and light guide elements or the like means.

### BACKGROUND OF THE INVENTION

1. Field of the Invention

The present invention relates to a light manipulating device, and more particularly to a sunlight manipulating device.

2. Description of the Prior Art

Solar energy belong to clean energy and inexhaustible, and therefore how to effectively utilizesolar energy is the main development direction of industry. At present, the major application of solar energy includes generating electric power, heating or illuminating. In order to effectively utilize solar energy, conventional solar cells are mostly set in space in direct sunlight, i.e. setting in outdoors. The life of solar cells setting in outdoors may be shortened due to climatic factors.

In addition, if the power consumption for illumination is greater than the amount of power generation by solar energy, the introduction of sunlight for illumination is obviously better for energy utilization. However, most of the conventional solar cell is set in facing the sun and large area manner to facilitate absorbing solar energy. In other words, the solar cell shadows the most sunlight which results the shadowed sunlight cannot be used as illumination purpose. To move the solar cell with large area requires not only more space and it is not easy.

Accordingly, it is highly desirable to manipulate the sunlight to efficiently use solar energy.

### SUMMARY OF THE INVENTION

The present invention is directed to a sunlight manipulating device which uses a light focusing module and a light deflection module to guide sunlight to a target area, so that an installation of a solar cell, a heating device or a light guide element can be more flexible, such as in a sheltered environment or erected installation.

In one embodiment, the proposed sunlight manipulating device includes a light focusing module and a light deflection module. The light focusing module is configured for converging incident sunlight on a focal region. The light deflection module is arranged on the focal region or adjacent to the focal region to deflect the converged sunlight to a target area, wherein the target area is diverged from an optical axis of the light focusing module.

The objective, technologies, features and advantages of the present invention will become apparent from the following description in conjunction with the accompanying drawings wherein certain embodiments of the present invention are set forth by way of illustration and example.

### BRIEF DESCRIPTION OF THE DRAWINGS

The foregoing conceptions and their accompanying advantages of this invention will become more readily appreciated after being better understood by referring to the following detailed description, in conjunction with the accompanying drawings, wherein:

FIG. 1 is a diagram schematically illustrating a sunlight manipulating device according to the first embodiment of the present invention;

FIG. 2 is a diagram schematically illustrating a sunlight manipulating device according to the second embodiment of the present invention;

FIG. 3 is a diagram schematically illustrating a sunlight manipulating device according to the third embodiment of the present invention;

FIG. 4 is a diagram schematically illustrating a sunlight manipulating device according to the fourth embodiment of the present invention;

FIG. 5 is a diagram schematically illustrating a sunlight manipulating device according to the fifth embodiment of the present invention;

FIG. 6 is a diagram schematically illustrating a sunlight manipulating device according to the sixth embodiment of the present invention;

FIG. 7a and FIG. 7b are diagrams schematically illustrating a sunlight manipulating device according to the seventh embodiment of the present invention;

FIG. 8 is a diagram schematically illustrating a sunlight manipulating device according to the eighth embodiment of the present invention; and

FIG. 9 is a diagram schematically illustrating a sunlight manipulating device according to the ninth embodiment of the present invention.

### DESCRIPTION OF THE PREFERRED EMBODIMENT

Various embodiments of the present invention will be described in detail below and illustrated in conjunction with the accompanying drawings. In addition to these detailed descriptions, the present invention can be widely implemented in other embodiments, and apparent alternations, modifications and equivalent changes of any mentioned embodiments are all included within the scope of the present invention and based on the scope of the Claims. In the descriptions of the specification, in order to make readers have a more complete understanding about the present invention, many specific details are provided; however, the present invention may be implemented without parts of or all the specific details. In addition, the well-known steps or elements are not described in detail, in order to avoid unnecessary limitations to the present invention. Same or similar elements in Figures will be indicated by same or similar reference numbers. It is noted that the Figures are schematic and may not represent the actual size or number of the elements. For clearness of the Figures, some details may not be fully depicted.

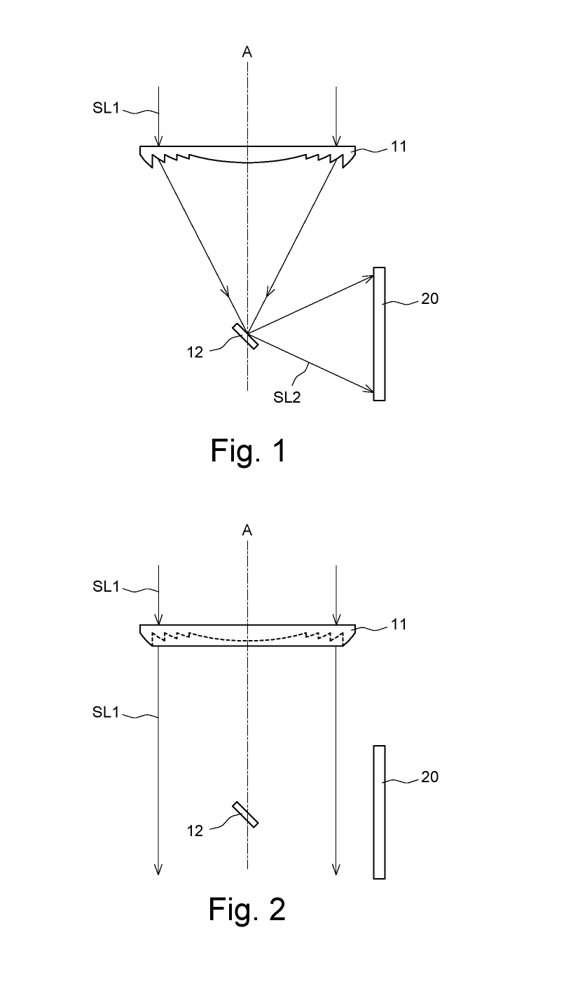

Referring to FIG. 1, a sunlight manipulating device according to the first embodiment of the present invention comprises a light focusing module 11 and a light deflection module 12. The light focusing module 11 can converge incident sunlight SL1 on a focal region. For example, the light focusing module 11 may be a Fresnel lens, but is not limited thereto. Other lenses or mirrors having the function of converging light can implement the present invention. In one embodiment, the focal region may be a focal point or focal line. The light deflection module 12 is arranged on the focal region or adjacent to the focal region converging the sunlight SL1, so that the light deflection module 12 deflects the converged sunlight SL2 to a target area 20. The target area 20 is diverged from an optical axis A of the light focusing module 11. In one embodiment, the light deflection module 12 may be a reflective element or a refractive element. In the embodiment shown in FIG. 1, the light deflection module 12 is a reflective element. It can be understood that the light deflection module 12 may be a single optical element which includes a plurality of reflecting surfaces or refractive surfaces. For example, the light deflection module 12 may be a prism. Furthermore, the position of the sun changes over time and the focal region also moves depending on the movement of the sun. Therefore, in one embodiment, the size or moveable path of the light deflection module 12 covers a movement trajectory of the focal region caused by movement of the sun.

In one embodiment, a light entrance surface of a solar cell, a heating device or a light guide element can be installed at the target area 20 to utilize the deflected sunlight SL2 from the light deflection module 12. According to the embodiment shown in FIG. 1, the installation of a solar cell, a heating device or a light guide element can be more flexible by using the sunlight manipulating device of the present invention to adjust the light path of the incident sunlight SL1. For example, the solar cell can be installed at a sheltered environment so that the damage of solar cell caused by wind, rain or other climatic factors can be avoided and the operating life of solar cell can be extended. In addition, the solar cell may be installed in erected manner to reduce the space required for the installation of solar cell. It can be understood that the sunlight SL2 irradiating to the target area 20 may not be used for any purpose.

Referring to FIG. 2 to illustrate the sunlight manipulating device according to the second embodiment of the present invention. Compared to the first embodiment shown in FIG. 1, the difference between the two is that the light focusing module 11 of the second embodiment is a variable focal length element, and the remaining components are the same as the first embodiment. In one embodiment, the trench of Fresnel lens can be filled with a material which has the same or similar refractive index with that of the Fresnel lens, so that the focusing effect of the light focusing module 11 will be significantly reduced. At this time, the incident sunlight SL1 passing through the light focusing module 11 is almost no convergence and most of the incident sunlight SL1 will not be deflected to the target area 20 by the light deflection module 12, and therefore, most of the incident sunlight SL1 can be used as the illumination purpose. On the contrary, the filled material can be drawn out from the Fresnel lens to restore the convergence function of the Fresnel lens, and therefore, the converged sunlight SL2 can be deflected to the target area 20 as the other of the applications. Briefly, it can be controlled whether the incident sunlight SL1 irradiates to the target area 20 or not by adjusting the focal length of the light focusing module 11. It can be understood that the target area 20 is diverged from a projection area along the optical axis A of the light focusing module 11 so as to avoid shadow the incident sunlight SL1 by the solar cell, the heating device or the light guide element installed at the target area 20.

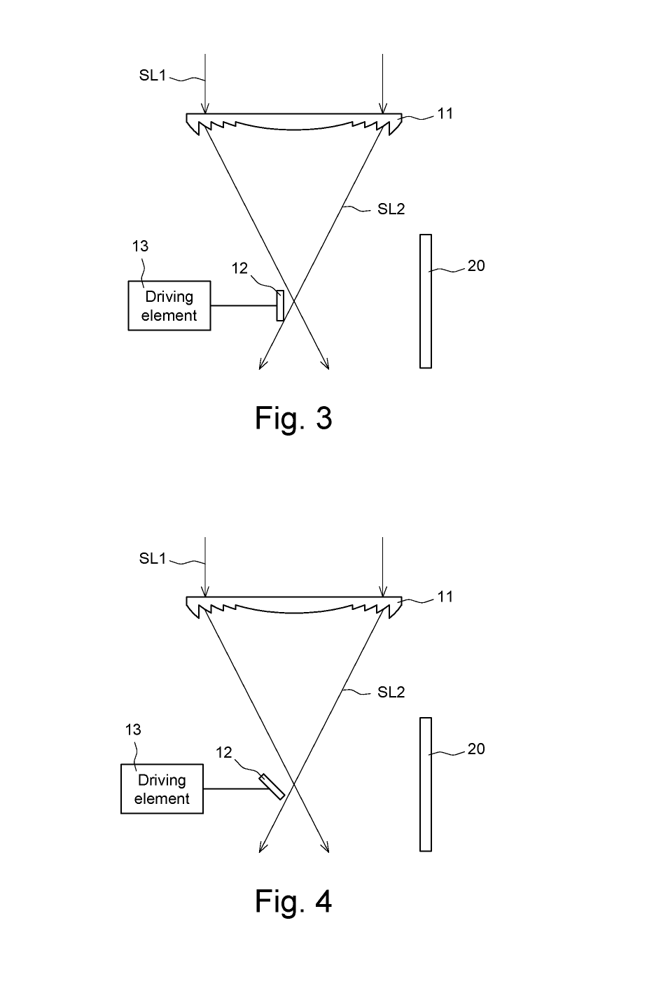

Referring to FIG. 3 and FIG. 4 to illustrate the sunlight manipulating device according to the third embodiment and fourth embodiment of the present invention. Compared to the first embodiment shown in FIG. 1, the difference between the two is that the third embodiment and fourth embodiment further comprise a driving element 13 connected with the light deflection module 12, and the remaining components are the same as the first embodiment. The driving element 13 is able to drive the light deflection module 12 in a manner of rotation (as shown in FIG. 3), linear movement (as shown in FIG. 4) or the combination thereof so as to make the light deflection module 12 diverge from the focal region. At this time, the converged sunlight SL2 from the light focusing module 11 will not be deflected to the target area 20 by the light deflection module 12, and the converged sunlight SL2 passing through the focal region will diffuse to form a wider range of irradiation region, for example, as an illumination purposes. It can be understood that part of the light deflection module 12 diverges from the focal region so that part of the converged sunlight SL2 is deflected to the target area 20 and another part of the converged sunlight SL2 is used for illumination purposes.

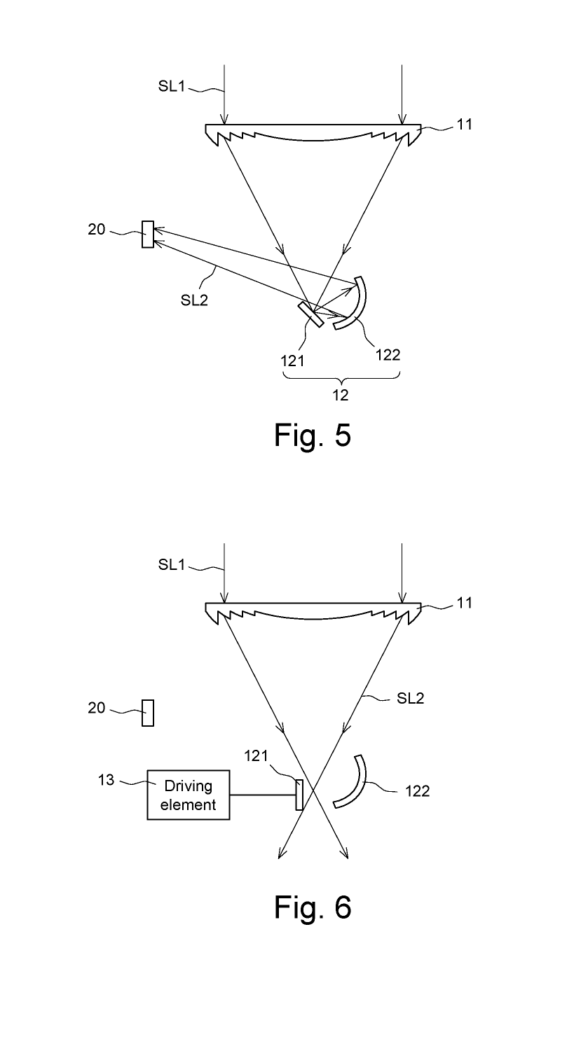

Referring to FIG. 5 to illustrate the sunlight manipulating device according to the fifth embodiment of the present invention. Compared to the first embodiment shown in FIG. 1, the difference between the two is that the light deflection module 12 of the fifth embodiment comprises a plurality of optical elements 121, 122, and the remaining components are the same as the first embodiment. As shown in FIG. 5, the optical element 122 includes a curved surface, so that the optical element 122 can further converge the sunlight SL2 converged by the light focusing module 11 to irradiate a smaller target area 20. It can be understood that the light deflection module 12 including a single optical element with curved surface is also able to implement the function of further converging the sunlight SL2.

Referring to FIG. 6 to illustrate the sunlight manipulating device according to the sixth embodiment of the present invention. Compared to the fifth embodiment shown in FIG. 5, the difference between the two is that the sixth embodiment further comprises a driving element 13 connected with the optical element 121 of the light deflection module 12, and the remaining components are the same as the fifth embodiment. As the third embodiment and the fourth embodiment shown in FIG. 3 and FIG. 4, the driving element 13 is able to drive the optical element in rotation or linear movement manner to make the optical element 121 diverge from the focal region of the light focusing module 11, so that the converged sunlight SL2 passing through the focal region will diffuse for the illumination purpose. It can be understood that the same purpose can be achieved by driving the light deflection module 12 including the optical elements 121, 122 to diverge from the focal region of the light focusing module 11 by the driving element 13. In one embodiment, the driving element 13 may drive the optical element 121 in rotation manner to make the sunlight SL2 converged by the light focusing module 11 deflect to other direction for irradiating a wider range of the target area 20, instead of deflecting to the optical element 122.

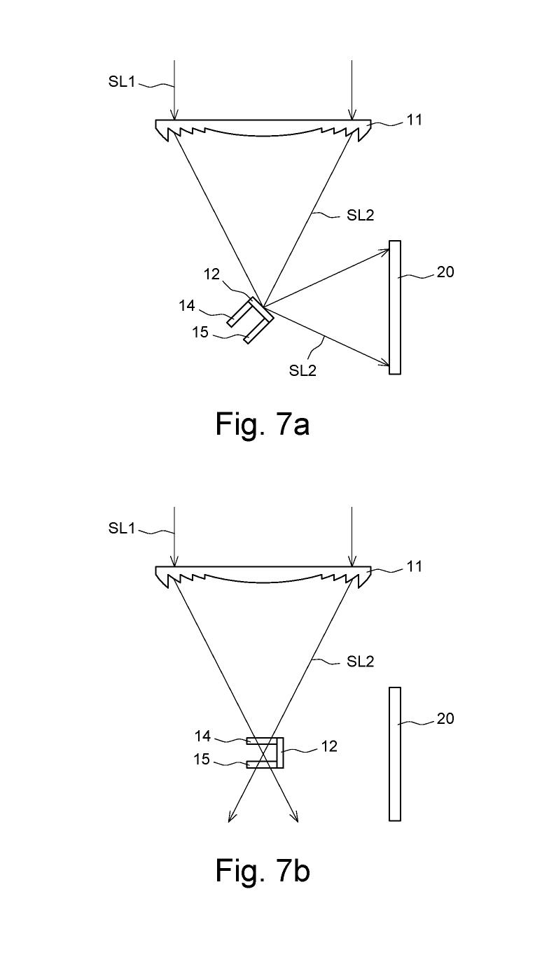

Referring to FIG. 7a and FIG. 7b to illustrate the sunlight manipulating device according to the seventh embodiment of the present invention. Compared to the first embodiment shown in FIG. 1, the difference between the two is that the seventh embodiment further comprises at least one of a filter element 14 and a scattering element 15, and the remaining components are the same as the first embodiment. The filter element 14 and the scattering element 15 may be driven by the driving element (not shown in FIG. 7a and FIG. 7b) to selectively move to the focal region or adjacent to the focal region in linear movement or rotation manner. According to the foregoing structure, for example as the illumination purpose, the filter element 14 or the scattering element 15 can be moved to the focal region to filter or scatter the converged sunlight SL2 to achieve better illumination effects.

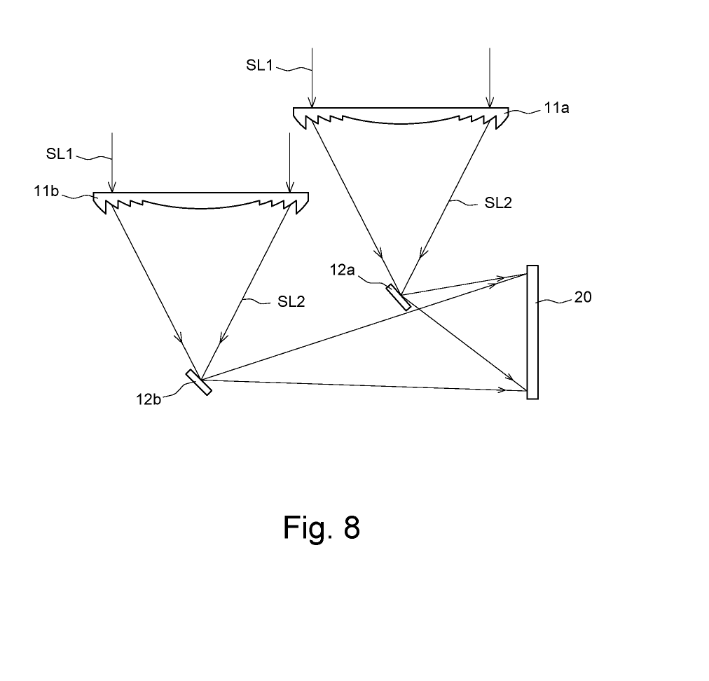

Referring to FIG. 8 to illustrate the sunlight manipulating device according to the eighth embodiment of the present invention. Compared to the first embodiment shown in FIG. 1, the difference between the two is that the light focusing module and the light deflection module of the eighth embodiment are a plurality, wherein the light focusing module 11a is corresponding with the light deflection module 12a and the light focusing module 11b is corresponding with the light deflection module 12b, and the remaining components are the same as the first embodiment. As shown in FIG. 8, the groups of the light focusing module and the light deflection module deflect the converged sunlight SL2 to the same target area 20. According to this structure, more sunlight can be obtained per unit area of the target area 20.

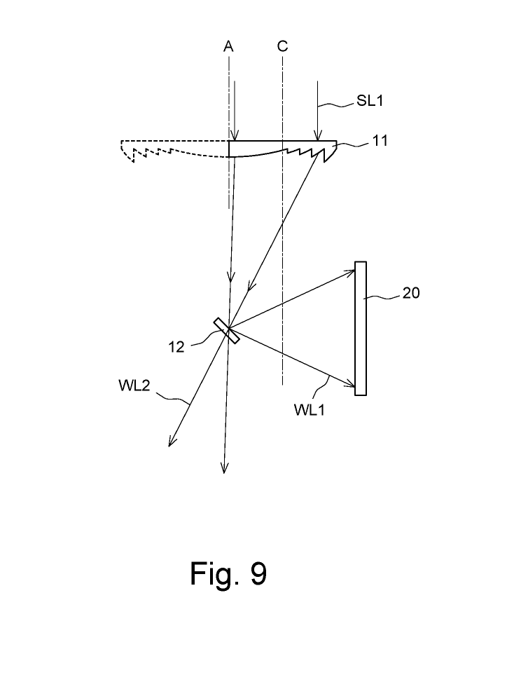

Referring to FIG. 9 to illustrate the sunlight manipulating device according to the ninth embodiment of the present invention. Compared to the first embodiment shown in FIG. 1, the difference between the two is that the light focusing module 11 is an asymmetric focusing optical element. Briefly, the focal region of the light focusing module 11 is diverged from a physical center axis C of the light focusing module 11. Therefore, the setting position of the light deflection module 12 is diverged from the physical center axis C of the light focusing module 11, which improve the installation of the light focusing module 12 be more flexible.

Referring to FIG. 9 again, in one embodiment, the light deflection module 12 may be a reflective filter. In other words, a first light WL1 of a first wavelength range among the converged sunlight can be deflected to the target area 20 by the light deflection module 12, and a second light WL2 of a second wavelength range among the converged sunlight transmits through the light deflection module 12. According to this structure, the second light WL2 can be used for illumination or irradiating plants to promote plants growth, and the first light WL1 can be for generating electric power or heating. It can be understood that the first light WL1 irradiating to the target area 20 may not be used for any purpose.

To summarize the foregoing descriptions, the sunlight manipulating device of the present invention uses the light focusing module and the light deflection module to adjust the light path of the incident sunlight and guide the sunlight to the target area, so that the installation of the solar cell, the heating device or the light guide element can be more flexible, such as in a sheltered environment or erected installation. In addition, the light path of the incident sunlight can be changed by controlling the light focusing module or the light deflection module so as to selectively adjust the application of the sunlight.

While the invention is susceptible to various modifications and alternative forms, a specific example thereof has been shown in the drawings and is herein described in detail. It should be understood, however, that the invention is not to be limited to the particular form disclosed, but to the contrary, the invention is to cover all modifications, equivalents, and alternatives falling within the scope of the appended claims.

What is claimed is:

1. A sunlight manipulating device comprising:
a light focusing module configured for converging incident sunlight on a focal region; and
a light deflection module arranged on the focal region or adjacent to the focal region to deflect the converged sunlight to a target area, wherein the target area is diverged from an optical axis of the light focusing module.

2. The sunlight manipulating device according to claim 1, wherein the light focusing module is a variable focal length element.

3. The sunlight manipulating device according to claim 1, wherein the light focusing module comprises a Fresnel lens.

4. The sunlight manipulating device according to claim 1, wherein the focal region is a focal point or focal line.

5. The sunlight manipulating device according to claim 1, wherein the size or moveable path of the light deflection module covers a movement trajectory of the focal region caused by movement of the sun.

6. The sunlight manipulating device according to claim 1, wherein the light deflection module is a reflective element or a refractive element.

7. The sunlight manipulating device according to claim 1, wherein the light deflection module comprises a curved surface.

8. The sunlight manipulating device according to claim 1, wherein the light deflection module comprises an optical element, and the optical element comprises a plurality of reflecting surfaces or refractive surfaces.

9. The sunlight manipulating device according to claim 1, wherein the light deflection module comprises a plurality of optical elements, and at least one of the optical elements comprise a curved surface.

10. The sunlight manipulating device according to claim 1, further comprising a driving element connected with the light deflection module to drive the light deflection module in at least one manner of linear movement or rotation to make the light deflection module diverge from the focal region.

11. The sunlight manipulating device according to claim 1, further comprising at least one of a filter element and a scattering element selectively moving to the focal region or adjacent to the focal region in linear movement or rotation manner.

12. The sunlight manipulating device according to claim 1, further comprising a driving element, wherein the light deflection module comprises a plurality of optical elements, and the driving element is connected with one of the optical elements to drive the optical element connected with the driving element in at least one manner of linear movement or rotation to make at least part of the optical element connected with the driving element diverge from the focal region.

13. The sunlight manipulating device according to claim 1, wherein the light focusing module and the light deflection module are a plurality, and sunlight is deflected to the same target area by the light focusing modules and the corresponding light deflection modules.

14. The sunlight manipulating device according to claim 1, wherein the target area is diverged from a projection area of the light focusing module along the optical axis of the light focusing module.

15. The sunlight manipulating device according to claim 1, wherein the target area comprises a light entrance surface of a solar cell, a heating device or a light guide element.

16. The sunlight manipulating device according to claim 1, wherein a first light of a first wavelength range among the sunlight is deflected to the target area by the light deflection module and a second light of a second wavelength range among the sunlight transmits through the light deflection module.

17. The sunlight manipulating device according to claim 1, wherein the light deflection module is a reflective filter.

18. The sunlight manipulating device according to claim 1, wherein a setting position of the light deflection module is diverged from a physical center axis of the light focusing module.
